(19) United States
(12) Patent Application Publication
(10) Pub. No.: US 2022/0157574 A1
(43) Pub. Date: May 19, 2022

(54) RING FOR SUBSTRATE EXTREME EDGE PROTECTION

(71) Applicant: Applied Materials, Inc., Santa Clara, CA (US)

(72) Inventors: Benjamin SCHWARZ, San Jose, CA (US); Michael D. WILLWERTH, Campbell, CA (US); Aditi MITHUN, San Jose, CA (US); Prabhat KUMAR, Fremont, CA (US); Grace MATHEW, Santa Clara, CA (US); Andreas SCHMID, Meyriez (CH)

(21) Appl. No.: 17/455,197

(22) Filed: Nov. 16, 2021

Related U.S. Application Data
(60) Provisional application No. 63/116,061, filed on Nov. 19, 2020.

(51) Int. Cl. H01J 37/32

(52) U.S. Cl. CPC H01J 37/32642; H01J 2237/334; H01J 37/32715

(57) ABSTRACT

Embodiments of the present disclosure provide a method and an apparatus for processing a substrate. The apparatus has a ring assembly. The ring assembly has an edge ring and a shadow ring. The edge ring has a ring shaped body. The edge ring body has a top surface and a bottom surface. Pin holes extend through the edge ring body from the top surface to the bottom surface. The shadow ring has a ring shaped body. The shadow ring body has an upper surface and a lower surface. Sockets are formed on the lower surface, wherein the sockets in the shadow ring body align with the pin holes in the edge ring body.

### CROSS-REFERENCE TO RELATED APPLICATIONS

This application claims priority to the U.S. Provisional Patent Application Ser. No. 63/116,061 filed Nov. 19, 2020 of which is incorporated herein by reference in its entirety.

### BACKGROUND

### Field

Examples of the present disclosure generally relate to a combination of rings which protect an extreme edge of a substrate undergoing plasma processing in a semiconductor processing chamber.

### Description of the Related Art

Electronic devices, such as flat-panel displays and integrated circuits, are commonly fabricated by a series of processes in which layers are deposited on the substrate and the deposited material layer is etched into desired patterns. The processes commonly include deposition systems, etch systems and other plasma and substrate processing systems. Specifically a plasma process includes supplying a process gas mixture to a vacuum chamber implying radiofrequency power [RF power] to excite the process gas into a plasma state. The plasma decomposes the gas mixture into ion species that perform the desired deposition or etch process.

As technology nodes progress, the need for increasingly smaller and selective processing capabilities are paramount. These capabilities extend from one edge of the substrate to another edge for maximizing the number of electronic devices on the substrate. Thus, the utilization of the substrate is maximized to promote when the layout for the devices utilize the area of the substrate as close to the edge as possible. However, during processing, such as an etch process, the plasma may etch the extreme edge of the substrate undesirably resulting in less useable area on the substrate for forming defect free devices.

Therefore, there is a need for an apparatus for performing a etch process while protecting the extreme edge of the substrate to maximize the usable area on the substrate for forming devices.

### SUMMARY

Embodiments of the present disclosure provide a method and an apparatus for processing a substrate. The apparatus has a ring assembly. The ring assembly has an edge ring and a shadow ring. The edge ring has a ring shaped body. The edge ring body has a top surface and a bottom surface. Pin holes extend through the edge ring body from the top surface to the bottom surface. The shadow ring has a ring shaped body. The shadow ring body has an upper surface and a lower surface. Sockets are formed on the lower surface, wherein the sockets in the shadow ring body align with the pin holes in the edge ring body.

In another embodiment, a plasma processing chamber is provided. The plasma processing chamber has a chamber body having sidewalls a lid and a bottom defining an interior volume. A controller is coupled to the chamber body. A substrate support assembly is disposed in the interior volume. The substrate support assembly has a chassis, an electrostatic chuck, a lift assembly and a ring assembly. The electrostatic chuck has a support surface configured to support a substrate thereon. The lift assembly is coupled to the chassis. Pins are coupled to the lift assembly and extending through the electrostatic chuck. The ring assembly has an edge ring and a shadow ring. The edge ring has a ring shaped body. The edge ring body has a top surface and a bottom surface. Pin holes extend through the edge ring body from the top surface to the bottom surface. The shadow ring has a ring shaped body. The shadow ring body has an upper surface and a lower surface. Sockets are formed on the lower surface, wherein the sockets in the shadow ring body align with the pin holes in the edge ring body.

In yet another embodiment, a method for etching a substrate is provided. The method begins by raising a shadow ring on a plurality of moveable pins with a lift assembly. A substrate is moved between a set of moveable pins onto a substrate support. The moveable pins are retracted by the lift assembly to lower the shadow ring. A plasma is struck to process the substrate disposed on the substrate support.

### BRIEF DESCRIPTION OF THE DRAWINGS

So that the manner in which the above recited features of the present disclosure are attained and can be understood in detail, a more particular description of the disclosure, briefly summarized above, may be had by reference to the embodiments thereof which are illustrated in the appended drawings.

FIG. 1 is a schematic cross-sectional view of a processing chamber according to one or more embodiments of the disclosure.

FIG. 2A is top plan view for a substrate support of the processing chamber of FIG. 1.

FIG. 2B is schematic cross section view for the substrate support of FIG. 2A.

FIGS. 3A-3B illustrate cross sectional partial views of the substrate support of FIG. 2B.

FIG. 4A is a top perspective view of an edge ring for the substrate support.

FIG. 4B is a bottom plan view of the edge ring.

FIG. 4C is a cross-section view of the edge ring taken through section line CC shown in FIG. 4A.

FIG. 5A is a top plan view of a shadow ring for the substrate support.

FIG. 5B is a bottom plan view of the shadow ring.

FIG. 5C is a cross-section view of the shadow ring taken through section line CC shown in FIG. 5A.

FIG. 6 illustrates a method for processing a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

A system is provided for patterning features and manufacturing nanostructures with desired small dimensions in a film stack, substrate. The system includes a combination of rings that protect the edge of the substrate from bevel attack and other non-uniformities leading to defects in the substrate. The combination of rings include an edge ring and a shadow ring. Either the edge ring or shadow ring may be supplied and replaced separately, that is, using a new one of one type of ring with an older ring of the other type of ring. The edge ring is configured to circumscribe the substrate. The edge ring has features that allow the lift pin movement to extend through the edge ring for adjusting the height of the shadow ring. The shadow ring is moveable to a lowered position on the edge ring and is configured to circumscribe overlay the substrate. The shadow ring effects the plasma sheath profile and protects the edge of the substrate from being attacked by the process chemistry. A lift motor is used to fine-tune the height of the shadow ring over the height of the substrate for altering the plasma sheath profile. When the substrate is placed in the processing chamber, the shadow ring is lowered by the motorized lift and placed at a defined height over the substrate edge. The shadow ring is configured to self-align with the edge ring, ensuring the shadow ring is concentric with the substrate. The disclosed system provides a mechanism to precisely control the height of the shadow ring over the substrate resulting in control of the plasma sheath and etch profile at the extreme edge of the substrate.

The term “substrate” as used herein refers to a layer of material that serves as a basis for subsequent processing operations and includes a surface to be etched. For example, the substrate can include one or more material containing silicon containing materials, group IV or group III-V containing compounds, dielectric materials, or any other materials such as metal nitrides, metal oxides and metal alloys, depending on the application. In one or more embodiments, the substrate can have a device or structure formed on or in the substrate. Additionally, the substrate is not limited to any particular size or shape.

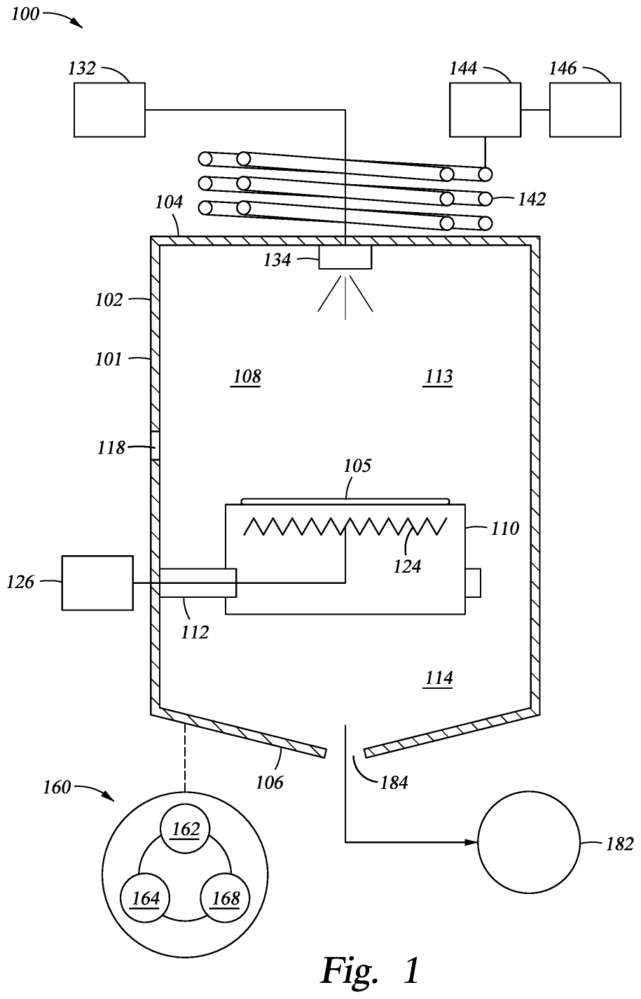

FIG. 1 is a schematic cross-sectional view of a processing chamber 100 according to one or more embodiments of the disclosure. The exemplary processing chamber 100 is suitable for patterning a material layer disposed on a substrate 300 in the plasma processing chamber 100. The exemplary processing chamber 100 is suitable for performing a patterning process. One example of the plasma processing chamber 100 that may be adapted to benefit from the disclosure is a CENTRIS® Sym3™ etching processing chamber, available from Applied Materials, Inc., located in Santa Clara, Calif. It is contemplated that other process chambers, including those from other manufactures, may be adapted to practice embodiments of the disclosure.

The plasma processing chamber 100 includes a chamber body 101 having an internal volume 108 defined therein. The chamber body 101 has sidewalls 102 and a bottom 106 which are coupled to ground. The sidewalls 102 may have a liner to protect the sidewalls 102 and extend the time between maintenance cycles of the plasma processing chamber 100. The dimensions of the chamber body 101 and related components of the plasma processing chamber 100 are not limited and generally are proportionally larger than the size of the substrate 105 to be processed therein. Examples of substrate sizes include 200 mm diameter, 250 mm diameter, and 450 mm diameter, among others sizes and shapes.

The chamber body 101 may be fabricated from aluminum or other suitable materials. A substrate access port 118 is formed through the sidewall 102 of the chamber body 101, facilitating the transfer of the substrate 105 into and out of the plasma processing chamber 100. The access port 118 may be coupled to a transfer chamber and/or other chambers of a substrate processing system (not shown).

The chamber body 101 supports a chamber lid 104 enclosing the internal volume 108. A substrate support assembly 110 has a chassis support 112 extending to the sidewall 102 for supporting the substrate support assembly 110 inside the internal volume 108. The substrate support assembly 110 divides the internal volume 108 into an upper volume 113 above the substrate support assembly 110 and a lower volume 114 below the substrate support assembly 110.

A pumping port 184 is formed through the bottom 106 of the chamber body 101 and connected to the lower volume 114. A pumping device 182 is coupled through the pumping port 184 to the lower volume 114 to evacuate the internal volume 108 and control the pressure therein. The pumping device 182 may include one or more pumps and throttle valves.

A gas panel 132 is coupled by a gas line to the chamber body 101 to supply process gases into the internal volume 108. The gas panel 132 may include one or more process gas sources and may additionally include inert gases, non-reactive gases, and reactive gases, if desired. Examples of process gases that may be provided by the gas panel 132 include, but are not limited to, hydrocarbon containing gas including methane (CH₄), sulfur hexafluoride (SF₆), silicon chloride (SiCl₄), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gasses may include nitrogen, chlorine, fluorine, oxygen and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O and H₂ among others.

The chamber lid 104 may include a nozzle 134. The nozzle 134 has one or more ports for introducing the process gases from the gas panel 132 into the upper volume 113. After the process gases are introduced into the plasma processing chamber 100, the gases are energized to form plasma. An antenna 142, such as one or more inductor coils, may be provided adjacent to the plasma processing chamber 100. An antenna power supply 146 may power the antenna 142 through a match circuit 144 to inductively couple energy, such as RF energy, to the process gas to maintain a plasma formed from the process gas in the upper volume 113 of the plasma processing chamber 100.

Alternatively, or in addition to the antenna power supply 146, process electrodes below the substrate 105 and/or above the substrate 105 may be used to capacitively couple RF power to the process gases to maintain the plasma within the internal volume 108. The operation of the antenna power supply 146 may be controlled by a controller, such as controller 160, that also controls the operation of other components in the plasma processing chamber 100.

The controller 160 may include support circuits 168, a central processing unit (CPU) 162 and memory 164. The CPU 162 may execute instructions stored in the memory 164 to control the process sequence, regulating the gas flows from the gas panel 132 into the plasma processing chamber 100 and other process parameters. Software routines may be stored in the memory 164. Software routines are executed by the CPU 162. The execution of the software routines by the CPU 162 controls the plasma processing chamber 100 such that the processes are performed in accordance with the present disclosure. For example, the software routine may control the operation of the substrate support assembly 110.

The substrate support assembly 110 supports the substrate 105 during processing. The substrate support assembly 110 comprises an electrode 124. The electrode 124 is coupled to an bias power supply 126 and provides a bias which attracts plasma ions, formed by the process gases in the upper volume 113, to the substrate 105 positioned thereon. The bias power supply 126 may cycle on and off, or pulse, during processing of the substrate 105.

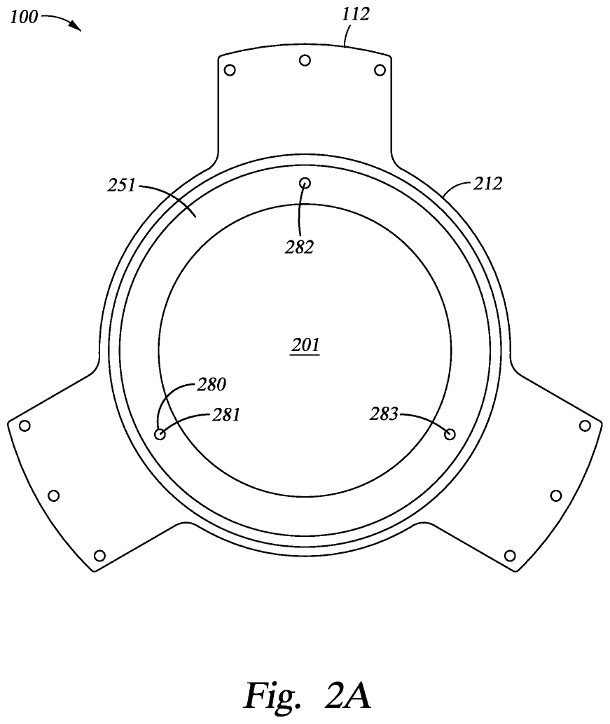

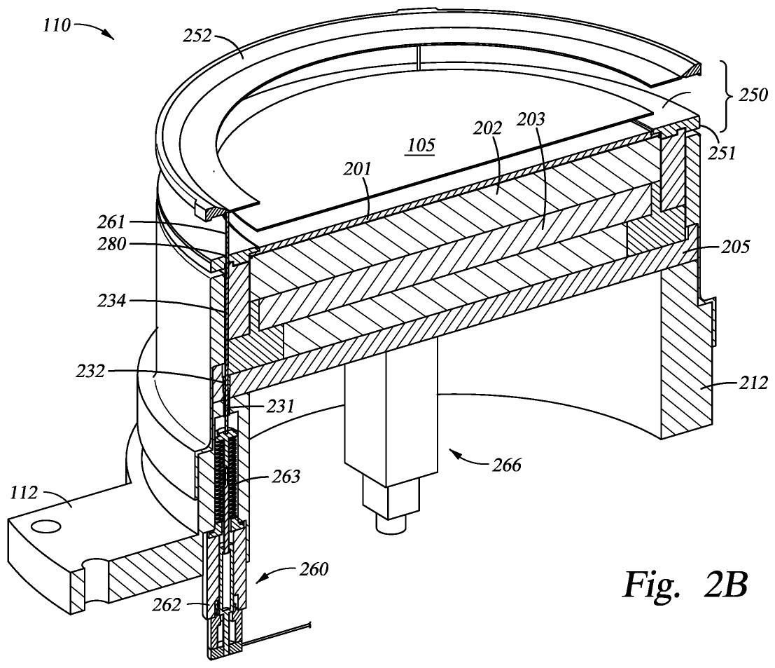

Turning to FIGS. 2A and 2B, FIG. 2A is top plan view for a substrate support of the processing chamber of FIG. 1. FIG. 2B is schematic cross section view for the substrate support of FIG. 2A. The substrate support assembly 110 may include an electrostatic chuck 201, a cooling plate 202, a facility plate 203, a ground plate 205, and a chassis 212. The chassis support 112 extends from the chassis 212 to support the substrate support assembly 110 in the internal volume 108 of the plasma processing chamber 100.

The electrostatic chuck (ESC) 201 uses the electrode 124 embedded therein to electrostatically attract the substrate 105 to the substrate support assembly 110. A chucking voltage of about 200 volts to about 2000 volts is provided to the electrode 124 for chucking and de-chucking the substrate 105 The substrate support assembly 110 may include heaters disposed therein, such as in the ESC 201, for heating the substrate. The cooling plate 202 supports the ESC 201 and may include conduits for circulating a heat transfer fluid to maintain a temperature of the ESC 201 and substrate 105 disposed thereon the ESC 201. To mitigate process drift and time, the temperature of the substrate 105 may be maintained substantially constant by the cooling plate 202 throughout the time the substrate 105 is in the plasma processing chamber 100.

The ESC 201 is configured to perform in the temperature range required by the thermal budget of the device being fabricated on the substrate 105. For example, the ESC 201 may be configured to maintain the substrate 105 at a temperature of about minus about 25 degrees Celsius to about 500 degrees Celsius for certain embodiments.

Lift pins move through the substrate support assembly 110 to lift the substrate 105 above the substrate support assembly 110, i.e., ESC 201, to facilitate access to the substrate 105 by a transfer robot (not shown) or other suitable transfer mechanism.

A ring assembly 250 is disposed on the ESC 201 and along the periphery of the substrate support assembly 110. The ring assembly 250 includes an edge ring 251 and a shadow ring 252. The edge ring 251 is disposed on the ESC 201. The edge ring 251 is sized to circumscribe the substrate 105. The shadow ring 252 is moveable to a lower position such that the shadow ring 252 is in contact with the edge ring 251 and overlaps an outer perimeter of the substrate 105. The ring assembly 250 is configured to shape the plasma sheath profile, confine etching gases to a desired portion of the exposed top surface of the substrate 105, and additionally shield the top surface of the substrate support assembly 110 from the plasma environment inside the plasma processing chamber 100.

A lift assembly 260 is disposed in the substrate support assembly 110. The lift assembly 260 is configured to move the shadow ring 252 between a raised and a lowered position. In the lowered position, the shadow ring 252 may be disposed on the edge ring 251 or near to the edge ring 251. The lift assembly 260 a mechanism to precisely control the height of the shadow ring 252 over the substrate 105 resulting in control of the plasma sheath and etch profile at the extreme edge of the substrate 105.

It is contemplated that the substrate support assembly 110 has three lift assemblies 260 disposed within the substrate support assembly 110 for balancing and moving the shadow ring 252. The lift assembly 260 has a motor 262, bellows 263 and a pin 261.

The motor 262 is operable to move the pin 261 upwards and downwards between a raised and lowered position. The motor 262 may be a linear actuator, pneumatic, hydraulic, stepper, servo, gear or other suitable motor for providing vertical displacement of the pin 261. The motor 262 may be configured with a hard stop as well as an optical encoder for determining the stroke or movement of the pin 261. The optical encoder is configured to provide feedback to the controller for a precise vertical location of the pin 261. The optical encoder allows precise control of the motor 262 for positioning the shadow ring 252 supported on the pin 261. In one example, the bellows 263 is configured to accommodate 2 inch or greater vertical movement of the pin 261. The bellows 263 maintains an airtight seal around the pin 261, allowing the pin 261 to move up and down while the interior of the plasma processing chamber 100 remains at vacuum pressure.

The lift assembly 260 may be coupled to the chassis 212. A hole 232 is provided in the chassis 212 for clearance of the pin 261 to extend through the chassis 212 without interference. A guide 231 may be disposed in the hole 232 to provide a bearing surface that promotes axial movement while preventing play, or horizontal movement, of the pin 261. The guide 231 may additionally extend to a ground plate hole 233 in the ground plate 205. The guide 231 may be a bushing preventing wobble or play of the pin 261. The guide 231 may be formed from ceramic material having an inner diameter for accommodating axial motion of the pin 261 through the guide 231.

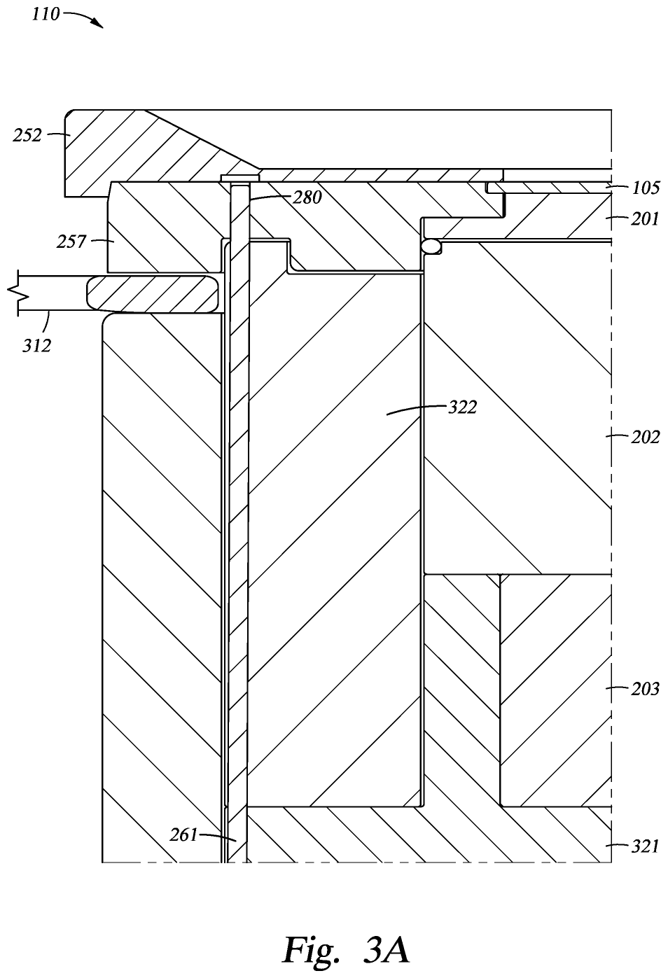

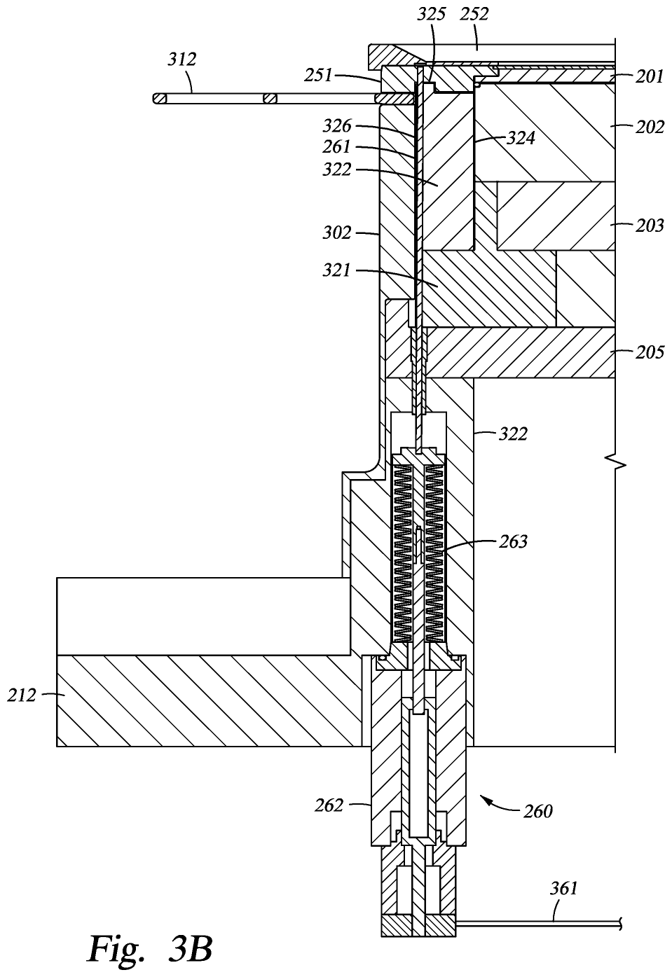

Turning to briefly, or additionally, to FIGS. 3A and 3B, FIGS. 3A-3B illustrate cross sectional partial views of the substrate support of FIG. 2B. The lift assemblies 260 are coupled by a control mechanism 361 to a controller such as controller 160. The control mechanism 361 may be a fluid conduit for supplying back and forth a control fluid, such as hydraulic or pneumatic fluid, to operate the motor 262. Alternately, the control mechanism 361 may be a cable for transmitting instructions or electrical power to operate the motor 262.

An isolator assembly is provided that includes a lower isolator ring 321 and an upper isolator ring 322. The upper isolator ring 322 has an outer surface 326 and an inner surface 324. The upper isolator ring 322 has a top surface 325 and a bottom surface 327. The bottom surface 327 of the upper isolator ring 322 contacts the lower isolator ring 321. The inner surface 324 of the upper isolator ring 322 is in contact with the cooling plate 202. The outer surface 326 of the upper isolator ring 322 is in contact with an outer sidewall, or cathode liner 302, of the substrate support assembly 110.

The lower isolator ring 321 and the upper isolator ring 322 make the sidewall of the substrate support assembly 110 less attractive to the plasma to prolong the maintenance life cycle of the substrate support assembly 110. Additionally, the cathode liner 302 to protect the sidewalls of the substrate support assembly 110 from the plasma gases and extends the time between maintenance of the plasma processing chamber 100.

A pipe slot 234 extends through both the upper isolator ring 322 and the upper isolator ring 322. The pipe slot 234 is a hole in the body of the upper isolator ring 322 and extends from the bottom surface 327 to the top surface 325 along the outer surface 326 of the upper isolator ring 322. The pipe slot 234 provides clearance in the upper isolator ring 322 for the pin 261 move through the upper isolator ring 322. Thus, it should be appreciated that a diameter of the pipe slot 234 is greater than a 0.090 inch diameter of the pin 261. For example, the pipe slot 234 may have a diameter between about 0.092 inches to about 0.095 inches.

A plasma screen 312 extends from the sidewall of the substrate support assembly 110. In one example, the plasma screen 312 extends from the upper isolator ring 322. In another example, the plasma screen 312 extends from the cathode liner 302. The plasma screen 312 may extend from the substrate support assembly 110 to the sidewall 102 of the plasma processing chamber 100. The plasma screen 312 prevents plasma in the upper volume 113 from entering the lower volume 114.

A ring assembly 250 is disposed on the ESC 201 and along the periphery of the substrate support assembly 110. The ring assembly 250 includes an edge ring 251 and a shadow ring 252. The shadow ring 252 is moveably disposed on the edge ring. The edge ring 251 is disposed on the ESC 201. The edge ring 251 is sized to circumscribe the substrate 105. The shadow ring 252 is moveable to a lower position such that the shadow ring 252 is in contact with the edge ring 251 and overlaps an outer perimeter of the substrate 105. The ring assembly 250 is configured to confine etching gases to a desired portion of the exposed top surface of the substrate 105, while shielding the top surface of the substrate support assembly 110 from the plasma environment inside the plasma processing chamber 100.

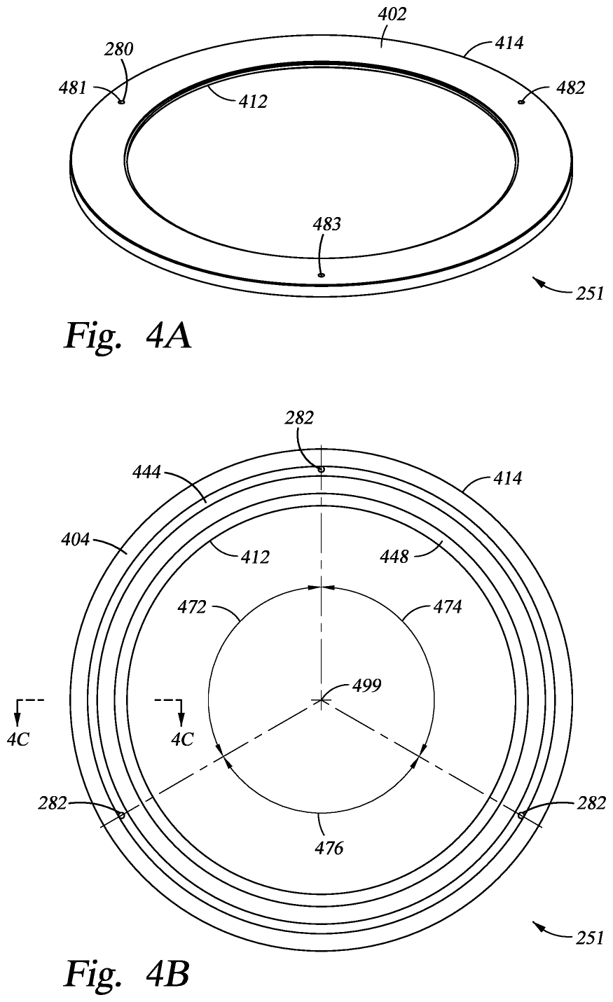

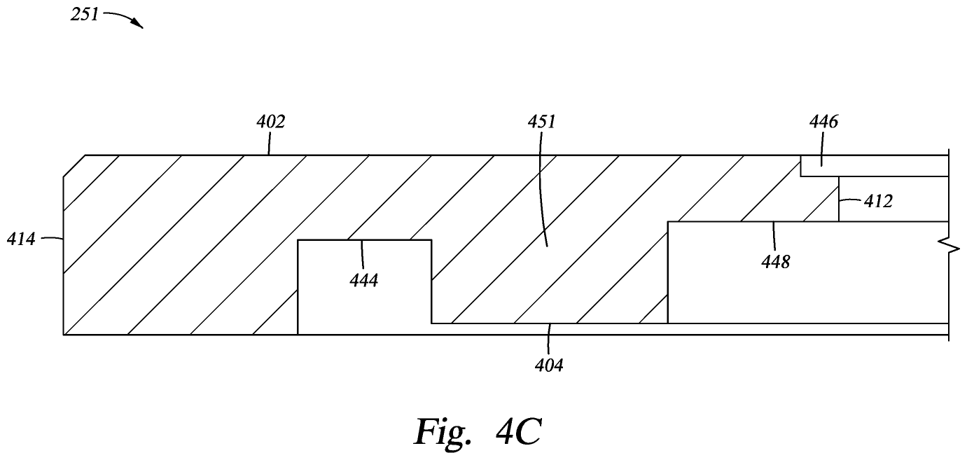

The discussion of the edge ring 251 now additionally refers to FIGS. 4A through 4C. FIG. 4A is a top perspective view of the edge ring 251 for the substrate support assembly 110. FIG. 4B is a bottom plan view of the edge ring 251. FIG. 4C is a cross-section view of the edge ring 251 taken through section line C-C shown in FIG. 4A.

The edge ring 251 has a body 451. The body 451 is ring shaped having an inner perimeter 412, an outer perimeter 414, a bottom surface 404 and a top surface 402. The body 451 is substantially concentric about a geometric center 499 of the edge ring 251. The body 451 has a lip 448. The lip 448 extends along the top surface to the inner perimeter 412. A step 446 is formed on the lip 448 between the inner perimeter 412 and the top surface 402. The step 446 is configured to support the substrate 105 thereon. A slot 444 is formed in the bottom surface and configured to interface with the upper isolator ring 322. The slot 444 and the upper isolator ring 322 maintain the position of the edge ring 251 on the substrate support assembly 110. That is, the slot 444 ensures the edge ring 251 remains centered on the substrate support assembly 110.

The edge ring 251 has pin holes 280. The pins 261 extend through the pin holes 280 in the edge ring 251 and contacts the shadow ring 252. The pin holes 280 extend entirely through the body 451 from the bottom surface 404 to the top surface 402. The pin holes 280 are configured to allow the pins 261 to pass entirely through the edge ring 251. The pin holes 280 may be arranged in a configuration to allow the substrate 105 to pass between the pin 261 extending through each pin hole 280. The pin holes 280 may be centered radially about the geometric center 499 of the edge ring 251. The pin holes 280 may be between about 7.00 inches to about 6.90 inches radially from the geometric center 499. In one example, the edge ring 251 has a first pinhole 481, a second pinhole 482, and a third pinhole 483. The first pinhole 481 may be oriented at a first angle 472 between about 110° to about 115° from the second pinhole 482. The second pinhole 482 may be oriented at a second angle 474 between 110° to about hundred and 15° from the third pinhole 483. This results in the first pinhole 481 being oriented at a third angle 476 between about 140° and about 130° from the third pinhole 483. Although it is not necessary for the first angle 472 and the second angle 474 to be equal, the third angle 476 is greater than the first angle 472 and the second angle 474 to accommodate the substrate 105 passing between the pin 261 extending from the first pinhole 481 and the third pinhole 483 without interference, or contact with the pin 261.

The shadow ring 252 rests on the three pins 261 extending through the edge ring 251 and operated by the lift assemblies 260. The lift assemblies 260 moves the shadow ring 252 vertically with respect to the edge ring 251 and the substrate support assembly 110. The shadow ring 252 is elevated by the pins 261 above the edge ring 251 to allow the substrate 105 to be moved onto and off of the substrate support assembly 110.

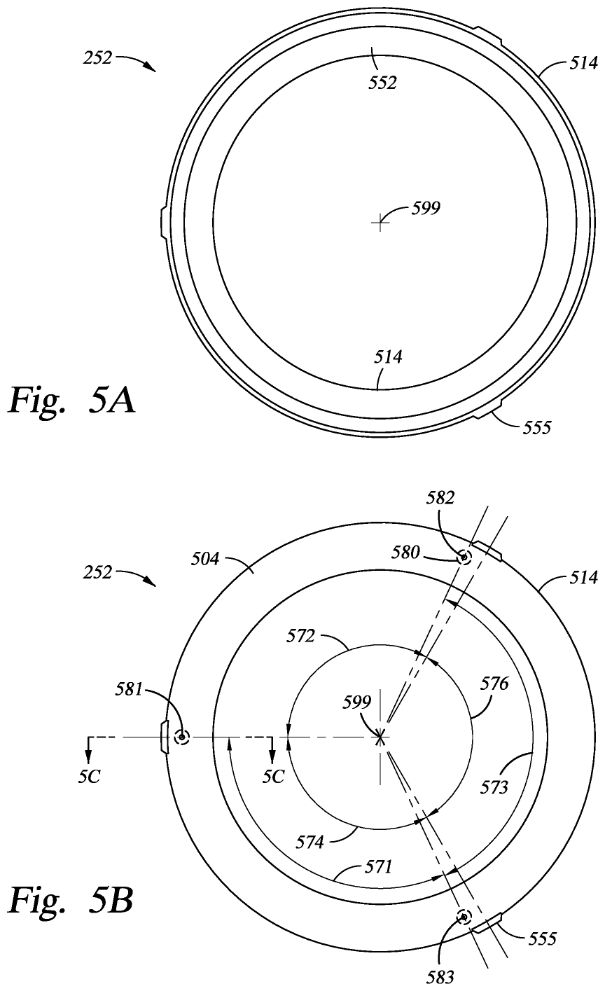

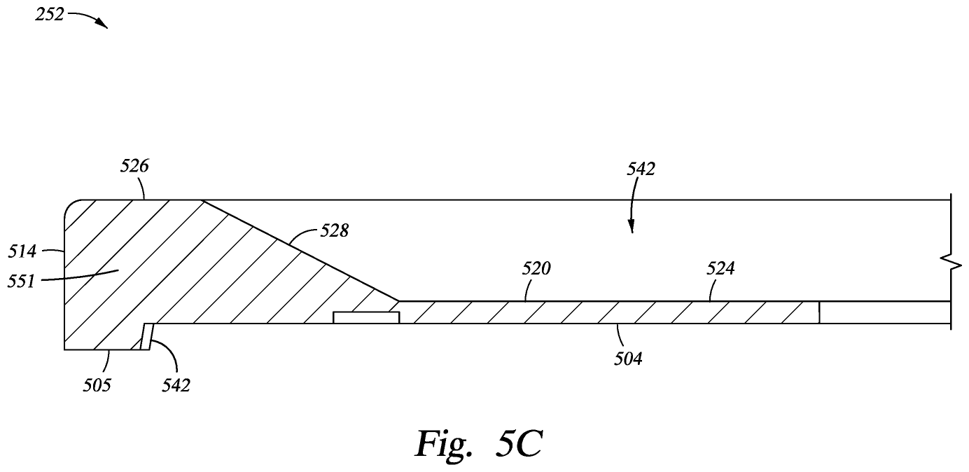

The discussion of the shadow ring 252 will now additionally reference FIGS. 5A through 5C. FIG. 5A is a top plan view of the shadow ring 252 for use on the substrate support assembly 110. FIG. 5B is a bottom plan view of the shadow ring 252. FIG. 5C is a cross-section view of the shadow ring 252 taken through section line C shown in FIG. 5A.

The shadow ring 252 has a body 551. The body 551 is substantially ring shaped and concentric about a geometric center 599 of the shadow ring 252. The body 551 has an outer perimeter 514 and an inner perimeter 512. The body 551 has a bottom surface 504 and a top surface 524. The body 551 may be formed from an aluminum oxide (Al₂O₃), quartz, silicon, molybdenum or other suitable material or combination of materials.

The top surface 524 has an upper top surface 526 and a lower top surface 524. The upper top surface 526 extends from the outer perimeter 514 to an inclined surface 528. The inclined surface 528 connects the upper top surface 526 to a lower top surface 524. A leg 505 extends from the bottom surface 504 along the outer perimeter 514 of the body 551. The leg 505 has an inner surface 542 opposite the outer perimeter 514. The inner surface 542 has an inner diameter sized to be greater than the outer perimeter 414 of the edge ring 251.

A plurality of tabs 555 extend out and downward from the outer perimeter 514 of the shadow ring 252. The tabs 552 align and center the shadow ring 252 on the substrate support assembly 110. In one example, the shadow ring 252 has three tabs 555. The tabs 552 may be equally spaced, for example, at 120° offset from an adjacent tab of the tabs 552. However, it should be appreciated that other spacing for the tabs 552 may be used.

The sockets 580 are formed into the body 551 of the shadow ring 252. The sockets 580 may be milled, ground, stamped or otherwise formed in the body 551. Each socket 580 is configured to accept one of the pins 261, and prevent the shadow ring 252 from moving laterally when supported by the pins 261. Alternately, the sockets 582 may have a replaceable bushing, insulator, pad or other insert to prevent wear of the shadow ring 252.

The sockets 580 may be centered radially about the geometric center 599 of the shadow ring 252. The sockets 580 may be between about 7.00 inches to about 6.90 inches radially from the geometric center 599. In one example, the shadow ring 252 has a first socket 581, a second socket 582, and a third socket 583. The first socket 581 may be oriented at a first angle 572 between about 110° to about 115° from the second socket 582. The second socket 582 may be oriented at a second angle 576 between 110° to about hundred and 15° from the third socket 583. This results in the first socket 581 being oriented at a third angle 574 between about 140° and about 130° from the third socket 581. The sockets 580 in the shadow ring 252 align with the pin holes 282 in the edge ring 251 when the geometric center 599/499 of both the shadow ring 252 and the edge ring 251 are aligned.

The configuration described above with respect to the geometric arrangement of the socket 580 in the shadow ring 252 and the pin hole 480 in the edge ring 251 provides a separation of the pins 261 in at least one location that is greater than the diameter of the substrate 105. For example, in the arrangement where the pins 261 are between about 7.0 inches and 6.90 inches from the geometric center 499/599, and the angle between one pair of pins 261 is between 130 degrees and 140 degrees, the pins 261 may have an opening or lateral separation between a pair of adjacent pins 261 of between about 370 mm and about 387 mm to accommodate the substrate 105 transfer between the pins 261. It should be appreciated that as the plasma processing chamber 100 is configured for different size substrates 105, the size of the shadow ring 252 and edge ring 251 are similarly sized and therefore change the opening between adjacent pins 261 for accommodating substrate transfer between the pins 261.

In operation, the controller 160 sends instructions to the lift assembly 260 for extending the pin 261 through the edge ring 251 to lift the shadow ring 252. The substrate 105 may be placed on the substrate support assembly 110 by a robot (not shown) extending through the opening formed between a first and second pin (pins 261) in the first and second pin holes 481/482, the edge ring 251 and the shadow ring 252. After retraction of the robot and the substrate 105 is resting on the ESC 201, the controller 160 sends instructions to the lift assembly 260 for lowering the pins 261 to lower the shadow ring 252 onto the edge ring 251. The shadow ring 252 extends over the substrate 105 along the inner perimeter 512 to protect the edge of the substrate 105. Advantageously, the shadow ring 252 prevents plasma during processing from undesirably attacking the substrate 105 backside and edge with process chemistry, i.e., bevel edge attack. Additionally, the lift assembly 260 allows fine tune adjustment of the height of the shadow ring 252 over the substrate 105 resulting in control of the plasma sheath and etch profile at the extreme edge of the substrate 105.

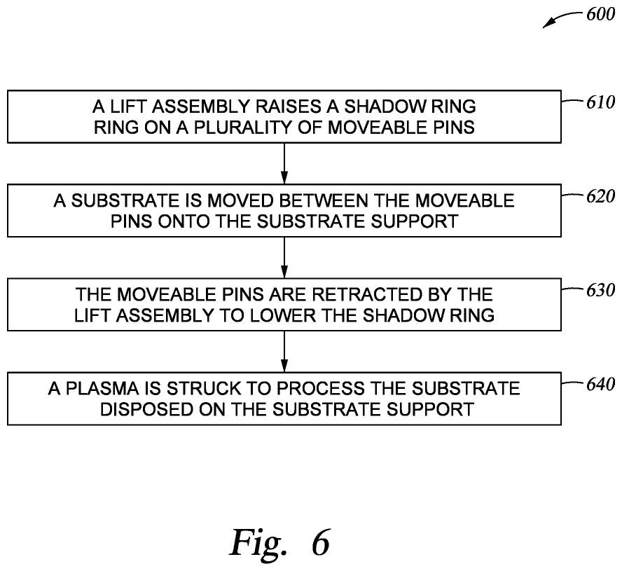

FIG. 6 illustrates a method 600 for processing a substrate. At block 610, a lift assembly raises a shadow ring on a plurality of moveable pins. The shadow ring being ring shaped and having a shadow ring interior diameter and a shadow ring outer diameter. The moveable pins extend through an edge ring disposed on a substrate support. At block 620, a substrate is moved between the moveable pins onto the substrate support. The edge ring being ring shaped and having an edge ring interior diameter and an edge ring outer diameter. The edge ring interior diameter is greater than the shadow ring interior diameter. The edge ring exterior diameter is smaller than the shadow ring exterior diameter. The edge ring interior diameter is greater than a substrate diameter of the substrate. The substrate is circumscribed by the edge ring. At block 630, the moveable pins are retracted by the lift assembly to lower the shadow ring. The shadow ring interior diameter is smaller than the substrate diameter. At block 640, a plasma is struck to process the substrate disposed on the substrate support. In some examples, the shadow ring is supported on the moveable pins while the substrate is processed.

While the foregoing is directed to embodiments of the present disclosure, other and further embodiments of the disclosure may be devised without departing from the basic scope thereof, and the scope thereof is determined by the claims that follow.

We claim:

1. A ring assembly comprising:
an edge ring having a ring shaped body the edge ring body comprising:
a top surface and a bottom surface; and
pin holes extending through the edge ring body from the top surface to the bottom surface; and
a shadow ring having a ring shaped body, the shadow ring body comprising:
an upper surface and a lower surface; and
sockets formed on the lower surface, wherein the sockets in the shadow ring body align with the pin holes in the edge ring body.

2. The ring assembly of claim 1, wherein the edge ring body further comprises:
an edge ring exterior diameter on the edge ring body;
an edge ring interior diameter on the edge ring body;
a shadow ring outer diameter; and
a shadow ring inner diameter, wherein the edge ring exterior diameter is smaller than a shadow ring exterior diameter and the edge ring inner diameter is larger than the shadow ring interior diameter.

3. The ring assembly of claim 2, wherein the edge ring has three pin holes and the shadow ring has three sockets.

4. The ring assembly of claim 3, wherein the sockets are an indent which does not extend to the upper surface.

5. The ring assembly of claim 4, wherein the at least one set of the three pin holes are radially spaced apart at 130 degrees or more.

6. The ring assembly of claim 5, wherein pin holes are at least 6.9 inches from a center of the edge ring.

7. A plasma processing chamber comprising:
a chamber body having sidewalls a lid and a bottom defining an interior volume;
a controller coupled to the chamber body; and
a substrate support assembly disposed in the interior volume, the substrate support assembly comprising:
a chassis;
an electrostatic chuck having a support surface configured to support a substrate thereon;
a lift assembly coupled to the chassis;
pins coupled to the lift assembly and extending through the electrostatic chuck; and
a ring assembly disposed on the support surface, the ring assembly comprising:
an edge ring having a ring shaped body the edge ring body comprising:
a top surface and a bottom surface; and
pin holes extending through the edge ring body from the top surface to the bottom surface wherein the pins extend into and through the pin holes; and
a shadow ring having a ring shaped body, the shadow ring body comprising:
an upper surface and a lower surface; and
sockets formed on the lower surface, wherein the sockets in the shadow ring body align with the pin holes in the edge ring body.

8. The plasma processing chamber of claim 7, wherein the edge ring body further comprises:
an edge ring exterior diameter on the edge ring body;
an edge ring interior diameter on the edge ring body;
a shadow ring outer diameter; and
a shadow ring inner diameter, wherein the edge ring exterior diameter is smaller than a shadow ring exterior diameter and the edge ring inner diameter is larger than the shadow ring interior diameter.

9. The plasma processing chamber of claim 8, wherein the edge ring has three pin holes and the shadow ring has three sockets and wherein the sockets are an indent and do not extend to the upper surface.

10. The plasma processing chamber of claim 9, wherein the at least one set of the three pin holes are radially spaced apart at 130 degrees or more.

11. The plasma processing chamber of claim 10, wherein pin holes are at least 6.9 inches from a center of the edge ring.

12. The plasma processing chamber of claim 9, wherein the substrate support assembly further comprises:
an isolator disposed below the electrostatic chuck wherein the isolator has through holes aligned with the pin holes in the edge ring and the pin extends through the through hole.

13. The plasma processing chamber of claim 12, wherein the isolator comprises:
an upper isolator; and
a lower isolator, wherein the through holes extend through both the upper isolator and the lower isolator.

14. The plasma processing chamber of claim 13, wherein the lift assembly further comprises:
a motor operable to move the pin vertically; and
an optical encoder configured to provide feedback to the controller for a precise vertical location of the pin.

15. The plasma processing chamber of claim 14 further comprising:
a guide disposed in the chassis wherein the pin extends through the guide and the guide prevents wobble in the pin.

16. The plasma processing chamber of claim 11 wherein the shadow ring has 3 equally spaced tabs extending out and downward from the edge ring exterior diameter.

17. A method for etching a substrate, comprising:
raising a shadow ring on a plurality of moveable pins with a lift assembly;
moving a substrate between a set of moveable pins onto a substrate support;
retracting the moveable pins by the lift assembly to lower the shadow ring; and
striking a plasma to process the substrate disposed on the substrate support.

18. The method of claim 17, wherein the moveable pins extend through an edge ring disposed on the substrate support.

19. The method of claim 18, wherein edge ring exterior diameter is smaller than a shadow ring exterior diameter and an edge ring interior diameter is greater than a substrate diameter of the substrate while a shadow ring interior diameter is smaller than the substrate diameter.

20. The method of claim 17 wherein the shadow ring is supported on the moveable pins while the substrate is processed.
